(19) United States
(12) Patent Application Publication
(10) Pub. No.: US 2025/0349444 A1
(43) Pub. Date: Nov. 13, 2025

(54) NUCLEAR FUEL CLADDING AND METHOD FOR PRODUCING SUCH CLADDING

(71) Applicant: FRAMATOME, COURBEVOIE (FR)

(72) Inventors: Jérémy BISCHOFF, LYON (FR); PIERRE BARBERIS, UGINE (FR); Karl BUCHANAN, GENAS (FR)

(21) Appl. No.: 18/723,865

(22) PCT Filed: Dec. 26, 2022
(86) PCT No.: PCT/EP2022/087846

§ 371 Date: Jan. 20, 2025

(30) Foreign Application Priority Data
Dec. 27, 2021 (FR) FR2114546

(51) Int. Cl. G21C 3/07; C23C 14/16; G21C 21/02

(52) U.S. Cl. CPC G21C 3/07; C23C 14/16; G21C 21/02

(57) ABSTRACT

The invention relates to a nuclear fuel cladding produced with a substrate (14) which is made of pure zirconium or of a zirconium based alloy and a multilayer protective coating (16) which covers a surface (14B) of the substrate (14), the protective coating (16) comprising a main layer (18) made of pure chromium and one or more additional layers (20), each additional layer (20) being made of pure chromium or from a material made of chromium and, additionally, oxygen and/or nitrogen, with the possible presence of unavoidable impurities.

The present disclosure relates to the field of nuclear fuel cladding (hereinafter also called “cladding”) intended to contain nuclear fuel, more particularly nuclear fuel rod cladding, and to the manufacturing method thereof.

### BACKGROUND

The nuclear fuel including the fissile material is generally contained in a sealed cladding which prevents the dispersion of the nuclear fuel.

Nuclear fuel assemblies used in light water reactors or in heavy water reactors generally comprise a bundle of nuclear fuel rods, each nuclear fuel rod comprising a tubular cladding containing nuclear fuel, the cladding being closed by a respective plug at each of the two ends thereof.

The cladding of the nuclear fuel assemblies is made e.g. of zirconium or of zirconium alloy. Such zirconium alloys have high performance under normal conditions of use in nuclear reactors.

However, same can reach the limits thereof in particular in terms of temperature during severe accidental conditions, such as e.g. during a Loss of Coolant Accident (or LOCA).

During such an event, the temperature at the core of the nuclear reactor can reach more than 800° C. and the cooling fluid is essentially in the form of water vapor.

The above can cause a rapid degradation of the cladding of a nuclear fuel rod, in particular along with a release of hydrogen and a rapid oxidation of the cladding leading to the weakening thereof or even to the bursting thereof, and thus to the release of nuclear fuel out of the cladding.

It is possible to provide a cladding comprising a substrate made of zirconium alloy and covered with a protective coating made of chromium.

Such a chromium protective coating generally increases the tolerance of the cladding under normal conditions and under accidental conditions. However, the wear resistance of such a chromium protective coating is relatively low.

One of the aims of the present disclosure is to propose a cladding which exhibits improved behavior under normal conditions and under accidental conditions, while exhibiting improved wear resistance.

To this end, the present disclosure proposes a nuclear fuel cladding manufactured with a substrate made of pure zirconium or of zirconium alloy and a multilayer protective coating covering a surface of the substrate, the protective coating comprising a main layer made of pure chromium and one or a plurality of additional layers, each additional layer being made of pure chromium or of a material consisting of chromium and, furthermore, oxygen and/or nitrogen, with the possible presence of unavoidable impurities.

The addition of an additional layer made of pure chromium or consisting of chromium and, furthermore, of oxygen and/or of nitrogen, in particular a material made of chromium oxide, chromium nitride, chromium oxynitride or a combination of these compounds or made of chromium doped with oxygen and/or nitrogen, further improves the performance of the cladding covered with a main layer made of pure chromium, more particularly in terms of wear resistance, scratch resistance and/or permeation to fission and other corrosion products, resistance to hydriding and absorption of hydrogen by the substrate, depending on whether the additional layer is located over the main layer or under the main layer.

According to particular embodiments, the cladding comprises one or a plurality of the following optional features, taken individually or in all technically possible combinations:
at least one additional layer is made of pure chromium, chromium oxide, chromium nitride or chromium oxynitride or a combination of such materials;
at least one additional layer is made of metallic chromium doped with oxygen atoms and/or nitrogen atoms or wherein oxygen atoms and/or nitrogen atoms are implanted;
the cladding comprises a transition layer interposed between the main layer and an additional layer containing oxygen and/or nitrogen, the transition layer being made of metallic chromium doped with oxygen atoms and/or nitrogen atoms or metallic chromium wherein oxygen atoms and/or nitrogen atoms are implanted;
the transition layer has a concentration of oxygen atoms progressively increasing from the main layer toward the additional layer and/or has a concentration of nitrogen atoms progressively increasing from the main layer toward the additional layer;
the concentration of oxygen atoms of the transition layer at the interface thereof with the adjacent additional layer is substantially equal to the concentration of oxygen atoms of the adjacent additional layer and/or the concentration of nitrogen atoms of the transition layer at the interface thereof with the adjacent additional layer is substantially equal to the concentration of nitrogen atoms of the adjacent additional layer;
the thickness of the main layer is comprised between 3 μm and 30 μm;
the thickness of each additional layer is comprised between 10 nm and 5 μm;
at least one additional layer is located over the main layer;
at least one additional layer is located under the main layer.

The present disclosure further relates to a method of manufacturing a nuclear fuel cladding, the method of manufacturing comprising providing a substrate made of pure zirconium or zirconium alloy, and depositing a multilayer protective coating on a surface of the substrate, the deposition of the protective coating comprising the deposition of a main layer made of pure chromium by physical vapor deposition and the deposition of one or a plurality of additional layers, each additional layer being made of pure chromium or of a material consisting of chromium and, furthermore, of oxygen and/or of nitrogen, with the possible presence of inevitable impurities.

According to examples of embodiments, the manufacturing method comprises one or a plurality of the following optional features, taken individually or in all technically possible combinations:
at least one additional layer is made of pure chromium, chromium oxide, chromium nitride or chromium oxynitride or a combination of such materials;
at least one additional layer is made of metallic chromium doped with oxygen atoms and/or nitrogen atoms or metallic chromium wherein oxygen atoms and/or nitrogen atoms are implanted;
an additional layer is deposited by physical vapor deposition;
an additional layer is deposited by physical vapor deposition carried out in an atmosphere formed by a binary or ternary gas mixture containing a neutral gas and, furthermore, of oxygen and/or of nitrogen;
the manufacturing method comprises the formation of a transition layer interposed between the main layer and an additional layer, the transition layer being made of chromium doped with oxygen atoms;
the transition layer has a concentration of oxygen atoms progressively increasing from the main layer toward the adjacent additional layer;
the thickness of the main layer is comprised between 3 nm and 30 μm;
the thickness of each additional layer is comprised between 10 nm and 5 μm;
at least one additional layer is deposited after the main layer;
at least one additional layer is deposited before the main layer.

The present disclosure further relates to a nuclear fuel cladding obtainable by a method such as defined hereinabove.

### BRIEF SUMMARY OF THE DRAWINGS

The present disclosure and the advantages of the present disclosure will better understood upon reading the following description, given only as a non-limiting example, and made with reference to the enclosed drawings, wherein:

FIG. 1 is a schematic view in longitudinal section of a nuclear fuel rod illustrating a cladding of the nuclear fuel rod;

FIGS. 2 to 6 are schematic axial views in longitudinal section of claddings of nuclear fuel rod;

FIG. 7 is a sectional view of a protective coating;

FIG. 8 is a schematic view of an installation for depositing a coating on a substrate by physical vapor deposition.

### DETAILED DESCRIPTION

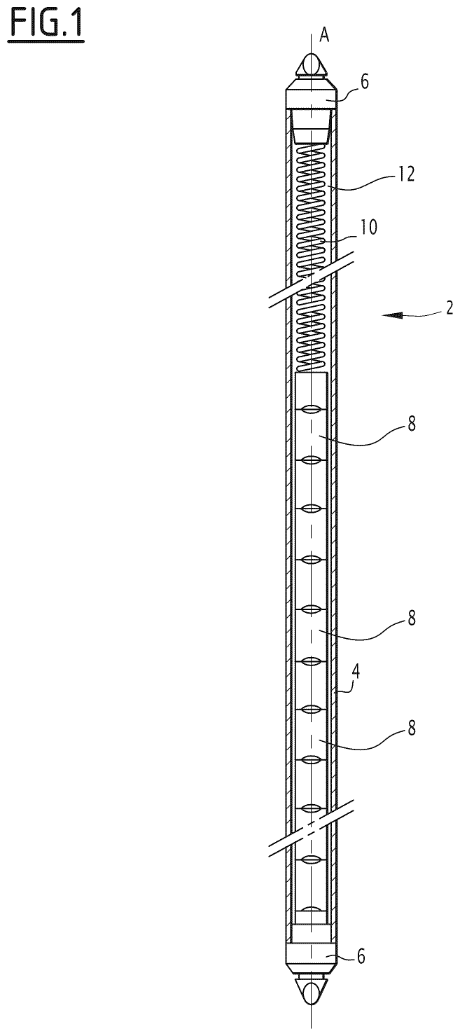

FIG. 1 illustrates a nuclear fuel rod 2 intended for being used in a light water reactor, in particular a pressurized water reactor (PWR) or a boiling water reactor (BWR), a “VVER” reactor, a “RBMK” reactor, or a heavy water reactor, e.g. a “CANDU” reactor.

The nuclear fuel rod 2 has the shape of a rod elongated along a longitudinal axis A.

The nuclear fuel rod 2 comprises a cladding 4 containing nuclear fuel. The cladding 4 is tubular and extends along the longitudinal axis A. The cladding 4 is sealed at each of the ends thereof by a respective plug 6.

The nuclear fuel is e.g. in the form of a stack of pellets 8 stacked axially inside the cladding 4, each pellet 8 containing fissile material. The stack of pellets 8 is also called a “fissile column”.

The nuclear fuel rod 2 comprises a spring 10 arranged inside the cladding 4, between the stack of pellets 8 and one of the plugs 6, for pushing the stack of pellets 8 toward the other plug 6. There is an empty space or plenum 12 between the stack of pellets 8 and the plug 6 on which the spring 10 bears.

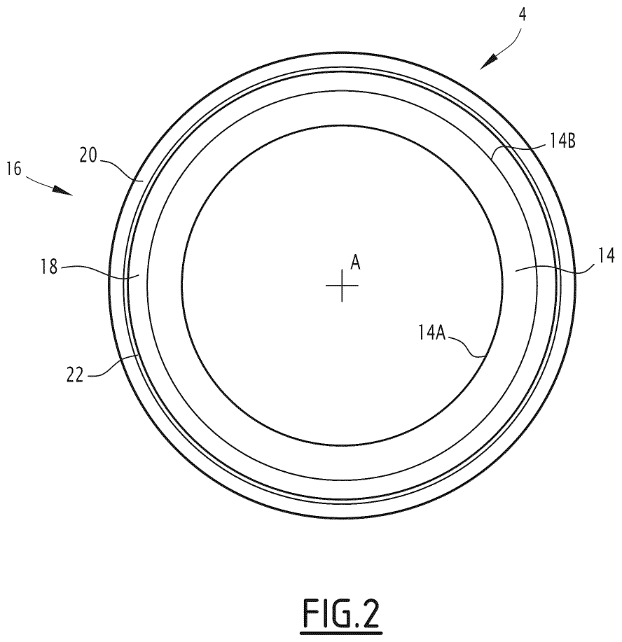

FIG. 2 represents an axial view of a cladding 4 of a nuclear fuel rod 2 intended to contain nuclear fuel.

The cladding 4 comprises a substrate 14 provided with a protective coating 16.

The cladding 4 is tubular and extends along a longitudinal axis A.

Correspondingly, the substrate 14 is tubular and extends along the longitudinal axis A. The substrate 14 is a tube.

The substrate 14 has e.g. an external diameter comprised between 8 mm and 15 mm, more particularly between 9 mm and 13 mm, and/or a length comprised between 1 m and 5 m, more particularly between 2 m and 5 m.

The substrate 14 is e.g. made of pure zirconium or of a zirconium alloy.

The expression “pure zirconium” refers to a material containing at least 99% by weight of zirconium and the expression “zirconium alloy” refers to an alloy containing at least 95% by weight of zirconium. The zirconium alloy is chosen e.g. from one of the known alloys such as M5, ZIRLO, E110, HANA, N36, Zircaloy-2 and Zircaloy-4.

The substrate 14 has an inner surface 14A oriented toward the inside of the cladding 4 and delimiting the space for accommodating the nuclear fuel.

The substrate 14 has an outer surface 14B intended to be oriented toward the outside of the cladding 4. The outer surface 14B is opposite the inner surface 14A.

The inner surface 14A is herein the surface oriented toward the inside of the tube-shaped substrate 14 and the outer surface 14B is the surface oriented toward the outside of the tube-shaped substrate 14.

The protective coating 16 covers the outer surface 14B of the substrate 14. The function of the protective coating 16 is to protect the outer surface 14B of the substrate 14 from the external environment. In the absence of a protective coating 16, the outer surface 14B of the cladding 14 would be exposed to the external environment.

The protective coating 16 is multilayer. The protective coating 16 comprises a plurality of superposed layers.

The protective coating 16 comprises a main layer 18 and one or a plurality of additional layers 20.

The main layer 18 is made of pure chromium.

“Made of pure chromium” means made of a material comprising at least 99% by weight of chromium. The rest of the material consists of unavoidable impurities.

Each additional layer 20 is located over the main layer 18 or under the main layer 18. Each additional layer 20 located over the main layer 18 is located on the side of the main layer 18 opposite the substrate 14. Each additional layer 20 located under the main layer 18 is located between the main layer 18 and the substrate 14.

The protective coating 16 comprises e.g. one or a plurality of additional layers 20 located over the main layer 18. The main layer 18 is located between the substrate 14 and each additional layer 20 located over the main layer 18.

The protective coating 16 comprises e.g. one or a plurality of additional layers 20 located under the main layer 18. The main layer 18 is located between the substrate 14 and each additional layer 20 located under the main layer 18.

Preferably, the surface layer of the protective coating 16 is an additional layer 20. The surface layer of the protective coating 16 is the outermost layer of the protective coating 16. Such surface layer is in contact with the external environment.

Each additional layer 20 is made of pure chromium or of a material consisting of chromium and, furthermore, of oxygen and/or of nitrogen, with the possible presence of unavoidable impurities.

Preferably, the material of each additional layer 20 consisting of chromium and, furthermore, of oxygen and/or of nitrogen, with the possible presence of unavoidable impurities, comprises at most 1% by weight of impurities, preferably at most 0.5% by weight of impurities.

The presence of impurities may be due e.g. to the presence of the impurities in the base material used to obtain the material of the additional layer 20.

For example, each additional layer 20 is made of pure chromium, of chromium oxide, more particularly of Cr₂O₃ or of an amorphous chromium oxide, of chromium nitride, of chromium oxynitride or of a combination of such materials or is made of metallic chromium doped with oxygen atoms and/or nitrogen atoms or is made of metallic chromium wherein oxygen atoms and/or nitrogen atoms are implanted.

A material of metallic chromium doped with oxygen atoms and/or nitrogen atoms or wherein oxygen atoms and/or nitrogen atoms are implanted refers to a material made of chromium the atoms of which are arranged according to the crystalline structure of chromium, oxygen atoms and/or nitrogen atoms being inserted into the crystalline structure of chromium, and more particularly replacing chromium atoms in the crystalline structure.

The doping with oxygen atoms and/or nitrogen atoms can take place e.g. during a physical vapor deposition of the additional layer 20.

An implantation of oxygen atoms and/or nitrogen atoms is generally carried out after a chromium deposition performed e.g. by physical vapor deposition.

The thicknesses of the substrate 14 and of the layers of the protective coating 16 are taken perpendicularly to the surface of the substrate 14 on which the protective coating 16 is deposited, herein the outer surface 14B.

The substrate 14 has e.g. a thickness comprised between 0.4 mm and 1 mm.

The main layer 18 has e.g. a thickness strictly less than the thickness of substrate 14.

The main layer 18 has e.g. a thickness comprised between 3 μm and 30 μm, more particularly a thickness comprised between 5 μm and 20 μm.

Preferably, the thickness of each additional layer 20 is strictly less than the thickness of the main layer 18.

The thickness of each additional layer 20 is e.g. comprised between 10 nm and 5 μm.

In FIGS. 2 to 6, the thickness of the substrate 14 and the thicknesses of the different layers of the protective coating 16 are not shown to scale, to keep the drawings clear.

Optionally, the protective coating 16 comprises one or a plurality of transition layers 22, each transition layer 22 being interposed between the main layer 18 and an additional layer 20 located over the main layer 18 or under the main layer 18. Each transition layer 22 is in contact on one side with the main layer 18 and on the other side with an additional layer 20 located over the main layer 18 or under the main layer 18.

Each transition layer 22 is made of metallic chromium doped with oxygen and/or nitrogen atoms and/or metallic chromium wherein oxygen and/or nitrogen atoms are implanted.

The material of each transition layer 22 consists of metallic chromium doped with oxygen atoms and/or nitrogen atoms or metallic chromium wherein oxygen atoms and/or nitrogen atoms are implanted, with the possible presence of unavoidable impurities.

The material of the transition layer 22 differs from a chromium oxide, a chromium nitride or a chromium oxynitride in that the material of the transition layer 22 is metallic chromium having the crystalline structure of chromium and wherein oxygen atoms and/or nitrogen atoms are included. The oxygen atoms and/or nitrogen atoms of the transition layer 22 are dispersed in the crystalline structure of the metallic chromium of the transition layer 22.

The concentration of oxygen atoms of the transition layer 22 is the number of oxygen atoms divided by the total number of atoms per unit volume. The concentration of oxygen atoms is e.g. expressed as a percentage of oxygen atoms in the material.

Similarly, the concentration of nitrogen atoms in the transition layer 22 is the number of nitrogen atoms divided by the total number of atoms per unit volume. The concentration of nitrogen atoms is e.g. expressed as a percentage of nitrogen atoms in the material.

Advantageously, the concentration of oxygen atoms of the transition layer 22 at the interface thereof with the adjacent additional layer 20 is substantially equal to the concentration of oxygen atoms of the additional layer 20.

If the additional layer 20 adjacent to the transition layer 22 is made of Cr₂O₃, the concentration of oxygen atoms at the transition layer 22 at the interface with the additional layer 20 is e.g. 60%.

At least one transition layer 22, and more particularly each transition layer 22, preferably has a concentration of oxygen atoms which increases, preferably progressively, depending on the thickness of the transition layer 22, from the main layer 18 toward the adjacent additional layer 20.

In a preferred embodiment, the additional layer 20 adjacent to the transition layer 22 is made of chromium oxide Cr₂O₃ and the concentration of oxygen atoms of the transition layer 22 increases, preferably progressively, from the main layer 18 to the adjacent additional layer 20 by a value of 0% up to a value of 60%.

In addition or as an option, the concentration of nitrogen atoms of each transition layer 22 at the interface thereof with the adjacent additional layer 20 is substantially equal to the concentration of nitrogen atoms of the additional layer 20.

If the additional layer 20 adjacent to the transition layer 22 is made of chromium nitride (CrN), the concentration of oxygen atoms of the transition layer 22 at the interface thereof with the additional layer 20 is e.g. 50%.

At least one transition layer 22, and more particularly each transition layer 22, preferably has a concentration of oxygen atoms which increases, preferably progressively, depending on the thickness of the transition layer 22, from the main layer 18 toward the adjacent additional layer 20.

In a preferred embodiment, the additional layer 20 adjacent to the transition layer 22 is made of chromium oxide CrO and the concentration of oxygen atoms of the transition layer 22 increases, preferably progressively, from the main layer 18 to the adjacent additional layer 20 by a value of 0% up to a value of 50%.

In a particular example of embodiment, at least one transition layer 22, and more particularly each transition layer 22, preferably has a concentration of oxygen atoms and a concentration of nitrogen atoms which increase, preferably progressively, depending on the thickness of the transition layer 22, from the main layer 18 toward the adjacent additional layer 20.

The thickness of each transition layer 22 is comprised e.g. between 10 nm and 1 μm.

As illustrated in FIG. 2, in an example of embodiment, the protective coating 16 comprises the main layer 18 and an additional layer 20 located over the main layer 18, a transition layer 22 being interposed between the main layer 18 and the additional layer 20.

The main layer 18 is e.g. immediately adjacent to the substrate 14. The main layer 18 is in contact with the substrate 14. The main layer 18 is deposited directly over the substrate 14.

The additional layer 20 is made e.g. of pure chromium, of chromium oxide and/or of chromium oxynitride or of metallic chromium doped with oxygen and/or nitrogen or of chromium wherein oxygen atoms and/or nitrogen atoms are implanted. In a particular embodiment, the additional layer 20 is made of chromium oxide, preferably Cr₂O₃ or an amorphous chromium oxide.

The additional layer 20 is preferably the surface layer of the protective coating 16 (i.e. the layer in contact with the external environment).

The protective coating 16 herein consists of the main layer 18, the additional layer 20 located over the main layer 18 and the transition layer 22 interposed between the main layer 18 and the additional layer 20.

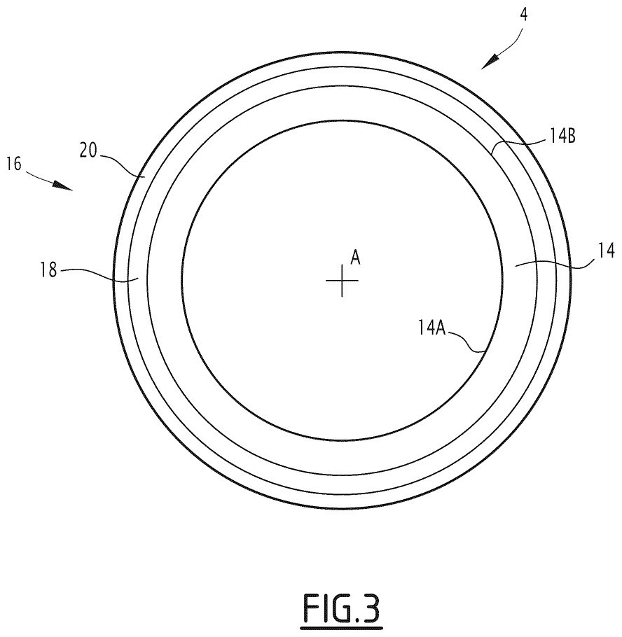

Other embodiments can be envisaged, as illustrated in FIGS. 3 to 6 wherein the numerical references to analogous elements have been repeated.

The cladding 4 shown in FIG. 3 differs from the cladding shown in FIG. 2 in that an additional layer 20 is applied directly over the main layer 18. The additional layer 20 is in contact with the main layer 18. The cladding 4 has no transition layer 22 between the main layer 18 and the additional layer 20 located over the main layer 18.

The protective coating 16 consists e.g. of the main layer 18 and of the additional layer 20 located over the main layer 18.

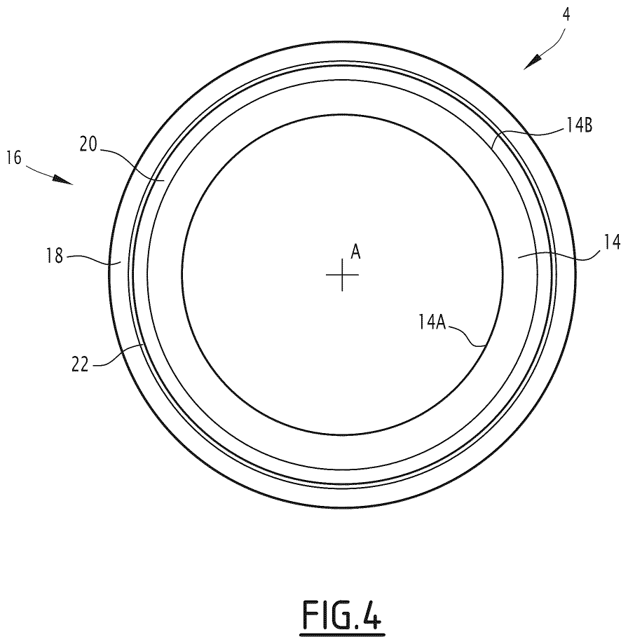

The cladding 4 shown in FIG. 4 differs from the cladding shown in FIG. 2 in that an additional layer 20 is located under the main layer 18, a transition layer 22 being interposed between the additional layer 20 and the main layer 18.

The additional layer 20 is e.g. deposited directly over the substrate 14, herein over the outer surface 14B of the substrate 14.

The protective coating 16 consists e.g. of the additional layer 20, the main layer 18 located over the additional layer 20, and the transition layer 22 interposed between the additional layer 20 and the main layer 18.

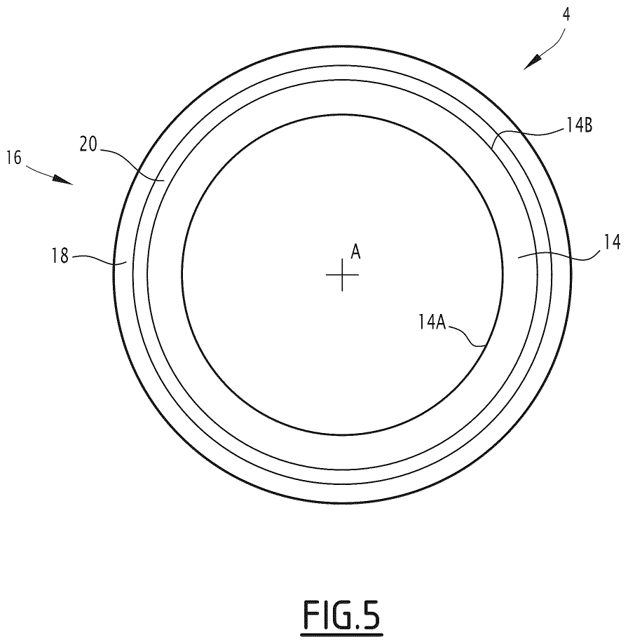

The cladding 4 shown in FIG. 5 differs from the cladding shown in FIG. 4 in that the main layer 18 is applied directly over the additional layer 20. The additional layer 20 is in contact with the main layer 18. The cladding 4 has no transition layer 22 between the additional layer 20 and the main layer 18 located over the additional layer 20.

The protective coating 16 consists e.g. of the additional layer 20 deposited over the outer surface 14B of the substrate 14 and by the main layer 18 located over the additional layer 20.

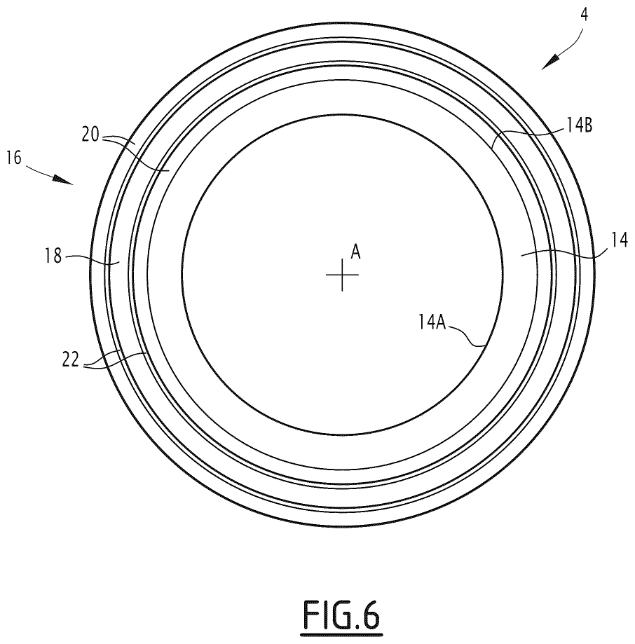

The cladding 4 shown in FIG. 6 differs from the cladding shown in FIG. 2 in that the protective coating 16 comprises an additional layer 20 located under the main layer 18 and an additional layer 20 located over the main layer 18. Optionally, a transition layer 22 is interposed between the main layer 18 and the additional layer 20 located under the main layer 18. Optionally as well, a transition layer 22 is interposed between the main layer 18 and the additional layer 20 located over the main layer 18.

The protective coating 16 consists e.g. of the main layer 18, of an additional layer 20 located under the main layer 18, of an additional layer 20 located over the main layer 18, a transition layer 22 is interposed between the main layer 18 and the additional layer 20 located under the main layer 18 and a transition layer 22 is interposed between the main layer 18 and the additional layer 20 located over the main layer 18.

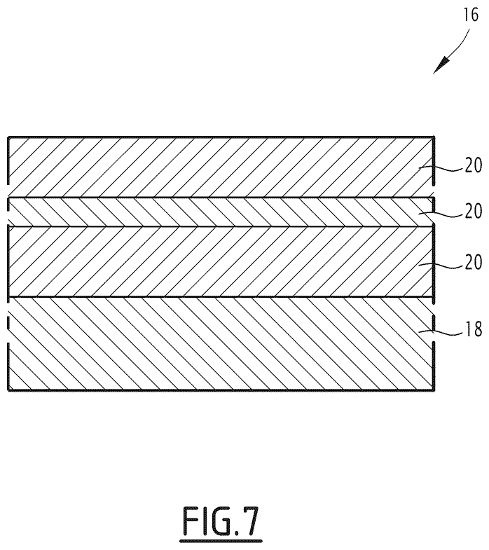

As illustrated in FIG. 7, in an example of embodiment, a protective coating 16 comprises at least one group of a plurality of adjacent additional layers 20. Each additional layer 20 of the group is in contact with the next layer in the stack of layers of the protective coating 16. In FIG. 7, three adjacent additional layers 20 are shown.

Preferably, each additional layer 20 adjacent to another additional layer 20 is made of a material different from the material of the other additional layer 20. In one embodiment, an additional layer 20 made of pure chromium is adjacent to another additional layer 20 made of a material consisting of chromium and, furthermore, of oxygen and/or of nitrogen, with the possible presence of unavoidable impurities, more particularly of a material made of chromium oxide, of chromium nitride, of chromium oxynitride, of metallic chromium doped with oxygen atoms and/or nitrogen atoms or metallic chromium wherein oxygen atoms and/or nitrogen atoms are implanted.

Advantageously, the group of a plurality of adjacent additional layers 20 comprises at least one additional layer 20 made of pure chromium which is interposed between two other additional layers 20, each of the two other additional layers 20 being made of a material consisting of chromium and, furthermore, of oxygen and/or of nitrogen, with the possible presence of unavoidable impurities, more particularly of a material made of chromium oxide, of chromium nitride, of chromium oxynitride, or of metallic chromium doped with oxygen atoms and/or nitrogen atoms or metallic chromium wherein oxygen atoms and/or nitrogen atoms are implanted.

In such case, the other two additional layers 20 located on either side of each additional layer 20 made of pure chromium are made of the same material or of different materials.

In one embodiment, each of the other two additional layers 20 is made of a material consisting of chromium and oxide, e.g. chromium oxide, or of a material consisting of chromium and nitrogen, e.g. A chromium nitride.

In a particular embodiment, the additional layer 20 made of pure chromium is interposed between two other additional layers 20 made of chromium nitride.

In an embodiment, the group of a plurality of adjacent additional layers 20 comprises at least one additional layer 20 made of pure chromium arranged alternately with other additional layers 20, each of the other additional layers 20 being made of a material consisting of chromium and, furthermore, of oxygen and/or of nitrogen, with the possible presence of unavoidable impurities, more particularly of a material made of chromium oxide, of chromium nitride, of chromium oxynitride, or of metallic chromium doped with oxygen atoms and/or nitrogen atoms or metallic chromium wherein oxygen atoms and/or nitrogen atoms are implanted.

The other additional layers 20 which are arranged alternately with the additional layer or layers 20 made of pure chromium, are made of the same material or of at least two different materials.

In a particular embodiment, the group of adjacent additional layers 20 comprises one or a plurality of additional layers made of pure chromium alternating with other additional layers 20 made of chromium nitride.

A protective coating 16 may comprise such a group of adjacent additional layers 20 located over the main layer 18 and/or such a group of adjacent additional layers 20 located under the main layer 18.

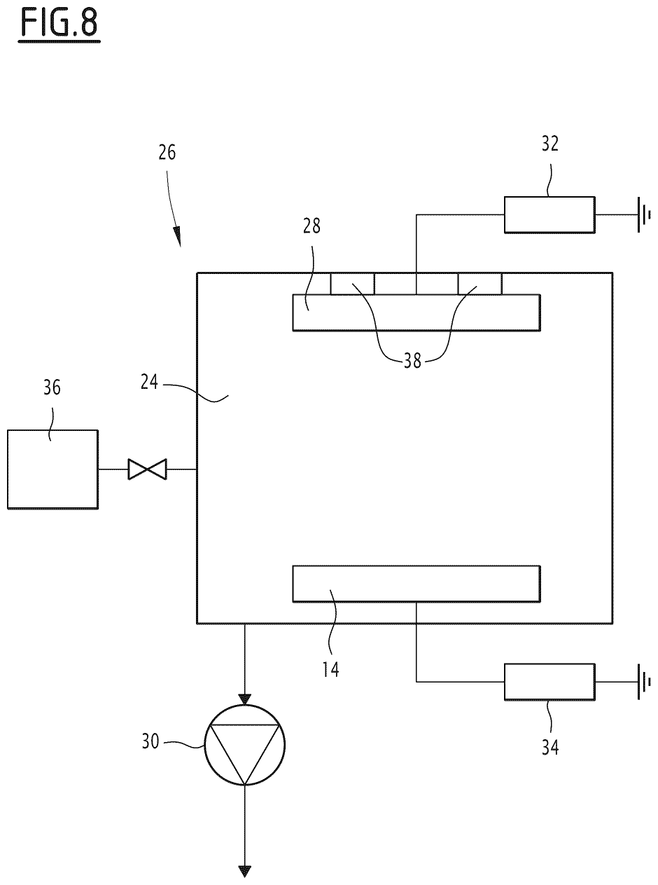

A method of manufacturing the cladding 4 will now be described with reference to FIG. 8.

The manufacturing process comprises a step of obtaining the substrate 14. When the substrate 14 is a tube, same is obtained e.g. in a known manner by pilgrim rolling, from a tubular blank with a diameter larger than the diameter of the substrate 14, the blank being deformed in such a way that the diameter thereof is progressively reduced and the length thereof is progressively increased, before being cut, if appropriate, to the desired length in order to obtain the substrate 14.

The manufacturing method then comprises a step of deposition of the main layer 18 over the outer surface 14B of the substrate 14 by physical vapor deposition.

As illustrated in FIG. 8, the physical vapor deposition of the main layer 18 is e.g. carried out under a controlled atmosphere in a chamber 24 of a physical vapor deposition installation 26, and more particularly under a rarefied atmosphere and consisting e.g. of a neutral gas, such as argon.

The neutral gas is chosen so as to prevent oxidation phenomena during the phase of deposition of a layer of the protective coating 16 over the substrate 14.

The physical vapor deposition is carried out e.g. by sputtering or by evaporation.

In one example of embodiment, the main layer 18 is deposited by physical vapor deposition by sputtering.

To this end, the substrate 14 and a target 28 made of chromium are placed in the chamber 24 wherein a rarefied atmosphere is generated, consisting e.g. of a neutral gas, such as argon, and an electric field is generated in the rarefied atmosphere, leading to producing a plasma containing electrically charged particles (electrons, ions, etc.), which are precipitated on the target 28 under the effect of the electric field and detach atoms from the target 28 (i.e. the target 28 is sputtered, hence the term sputtering), the atoms detached from the target 28 being deposited afterwards over the substrate 14.

The physical vapor deposition installation 26 comprises the chamber 24, the target 28 arranged inside the chamber 24, a pump 30 the inlet of which is fluidically connected to the chamber 24 so as to generate a rarefied atmosphere in the chamber 24, an electric generator 32 connected to the target 28, optionally, an electrical generator 34 connected to the substrate 14, and a gas supply device 36 fluidically connected to the chamber 24, e.g. to supply neutral gas (e.g. argon), oxygen and/or nitrogen.

Preferably, the physical vapor deposition is carried out by magnetron sputtering. In such a case, a magnetic field is generated, preferentially at least close to the target 28.

The provision of a magnetic field makes it possible to better control the trajectory of the electrically charged particles reaching the target 28, which leads to a better controlled rate of deposition of the main layer 18, more particularly a faster rate of deposition.

The magnetic field is generated e.g. by one or more permanent magnets 38, as illustrated in FIG. 3, and/or one or more electromagnets.

The manufacturing method comprises the deposition of at least one additional layer 20, also by physical vapor deposition.

The deposition of each additional layer 20 is performed e.g. in the same physical vapor deposition installation 26 as the physical vapor deposition of the main layer 18.

The deposition of each additional layer 20 is performed e.g. using the same physical vapor deposition technique as same used to perform the physical vapor deposition of the main layer 18.

The deposition of each additional layer 20 is performed e.g. by physical vapor deposition by sputtering, more particularly by magnetron sputtering.

The deposition of each additional layer 20 is performed using the same technique as for the deposition of the main layer 18, but differs in that same is performed, when necessary, in a controlled atmosphere containing, in addition to the neutral gas, oxygen and/or nitrogen for the formation of an additional layer of chromium oxide, of chromium nitride, of chromium oxynitride or of a combination thereof.

The oxygen and the nitrogen gases are e.g. fed into the chamber 24 by means of the gas supply device 36.

In one embodiment, only oxygen is fed into the controlled atmosphere in addition to the neutral gas. The controlled atmosphere is a binary gas mixture containing neutral gas and oxygen. It is possible thereby to obtain an additional layer 20 of chromium oxide.

In one embodiment, only nitrogen gas is fed into the controlled atmosphere. The controlled atmosphere is a binary gas mixture containing neutral gas and nitrogen. It is possible thereby to obtain an additional layer 20 of chromium nitride.

In one example of embodiment, oxygen and nitrogen gases are fed into the controlled atmosphere in addition to the neutral gas. The controlled atmosphere is a ternary gas mixture containing neutral gas, oxygen and nitrogen. It is thereby possible to obtain an additional layer containing chromium oxide, chromium nitride and/or chromium oxynitride.

In one embodiment, only the neutral gas is fed into the controlled atmosphere. It is thereby possible to obtain an additional layer 20 of pure chromium.

The layers of the protective coating 16 are deposited successively from the layer closest to the layer furthest away from the substrate 14.

Each additional layer 20 located under the main layer 18 is deposited before the main layer 18 and/or each additional layer 20 located over the main layer 18 is deposited after the main layer 18.

At the end of the deposition of the main layer 18 and of each additional layer 20, the cladding 4 comprises the substrate 14 the outer surface 14B of which is covered by the protective coating 16.

Where appropriate, the manufacturing method comprises the formation of each transition layer 22.

Each transition layer 22 is e.g. made by depositing a chromium layer by physical vapor deposition while feeding oxygen in the gaseous state into the atmosphere of the chamber 24.

The formation of a transition layer 22 over the main layer 18 is e.g performed after the deposition of the main layer 18, by continuing the physical vapor deposition of the chromium while feeding gaseous oxygen into the atmosphere of the chamber 24.

For the production of a transition layer 22 having a proportion of oxygen atoms which increases, preferably progressively, the proportion of oxygen in the atmosphere of the chamber 24 is e.g. increased or decreased over time, preferably progressively.

In a variant, instead of feeding gaseous oxygen into the atmosphere of the chamber 24, it is possible to feed in an oxygenated product which decomposes or evaporates by releasing oxygen into the controlled atmosphere.

In a variant, the transition layer 22 is obtained after the deposition of chromium by physical vapor deposition over a thickness corresponding to the thickness desired for the transition layer 22, then by performing an ion implantation of oxygen into the chromium layer.

Each physical vapor deposition (deposition of the main layer 18, deposition of each additional layer 20 and, if appropriate, deposition of each transition layer 22) can be performed with a direct current density (i.e. by applying a direct electric current to the target 28) or a pulsed current density (i.e. by applying a pulsed electric current comprising pulses).

Each physical vapor deposition by magnetron sputtering can be carried out according to one of the following techniques or a combination of at least two of the following techniques: direct current (DC) magnetron sputtering, pulsed direct current (or DC pulsed) magnetron sputtering, High Power Impulse Magnetron Sputtering (HiPIMS or HPMS), Magnetron Sputtering Bi-polar (MSB), Dual Magnetron Sputtering (MSB), Dual Magnetron Sputtering (Magnetron sputtering Bi-polar), Dual Magnetron Sputtering (DMS), Unbalanced Magnetron (UBM) Sputtering.

The deposition of the protective coating 16 by physical vapor deposition by magnetron sputtering is preferred, but the present disclosure is not limited to such a deposition technique.

In a variant, the deposition of each layer of the protective coating 16 can be performed using another technique, e.g. by physical vapor deposition by evaporation, more particularly by physical vapor deposition by electric arc, or by physical deposition by cold spray.

The addition of a main chromium layer 18 over the substrate 14 serves to improve the resistance to wear of the cladding 4 compared with a cladding 4 made of pure zirconium or zirconium alloy, which is not coated.

The further addition of an additional layer 20 made of pure chromium or of a material consisting of chromium oxide, of chromium nitride, of chromium oxynitride or of a combination of such compounds or made of chromium doped with oxygen and/or nitrogen, allows the performance of the cladding 4 to be further improved, more particularly in terms of resistance to wear, of resistance to scratches and/or of permeation to fission products.

Each additional layer 20 deposited by physical vapor deposition can be deposited in a controlled manner, with a thickness chosen, and more particularly a thickness sufficient for obtaining the desired performance.

The addition of an additional layer 20 over the main layer 18 can improve the resistance to wear and scratches, due to an increased hardness compared to the main layer 18. The resistance to wear limits the sensitivity of the cladding 4 to fretting. The resistance to scratches limits the risk of scratching on the outer surface of the cladding 4 when inserting the nuclear fuel rod 2 through the spacer grids of a nuclear fuel assembly.

Each additional layer 20 located over the main layer 18 or under the main layer 18, more particularly when same contains Cr₂O₃, serves to limit the permeation through the cladding 4 of fission products such as tritium coming from the inside of the cladding or of corrosion products such as hydrogen coming from the outer surface.

Hydrogen can increase the brittleness of the substrate 14 made of zirconium alloy and tritium can pollute the cooling fluid circulating in the core of the nuclear reactor.

An additional layer 20 located over the main layer 18 and containing chromium oxide, and in particular Cr₂O₃, may also gain a black color even before the insertion thereof into a core of a nuclear reactor, which may be favorable to heat transfers during transient phases of the nuclear reactor, more particularly during the start-up of the nuclear reactor.

An additional layer 20 located under the main layer 18, between the substrate 14 and the main layer 20, can reduce the formation of a Cr—Zr eutectic for high temperatures, typically for temperatures above 1330° C. The resistance of the cladding in the event of LOCA is improved.

It should be noted that the natural formation of an oxide on a zirconium alloy cladding takes place in a few days after being exposed to the presence water on the surface of the cladding. For example, the natural formation of an oxide on a zirconium alloy cladding of a nuclear fuel rod takes place in about five days after the insertion of the nuclear fuel assembly into the core of a nuclear reactor. The thickness of zirconium oxide thereby formed on the cladding quickly reaches about 100 nm and quickly provides protection to the zirconium alloy substrate.

In contrast, the natural formation of chromium oxide on a chromium protective coating in the presence of water on the coating is slow, e.g. by a factor of 10 to 20 times slower than for a zirconium alloy, and insufficient to provide protection to the coating as soon as the cladding is used in a core of a nuclear reactor. A chromium oxide thickness of 100 nm is reached only after 500 days in the reactor.

The protective coating comprising at least one additional layer is deposited during the manufacture of the cladding.

The deposition of a protective coating comprising at least one additional layer during the manufacture of the cladding provides protection from the beginning of the use of the cladding in a nuclear reactor core.

As such, it should be noted that the depositions of the chromium layers of the chromium protective coating are generally performed in an inert medium (with a rare gas such as argon) in order to prevent oxidation phenomena during the deposition of the coating of the chromium layer.

1. A nuclear fuel cladding manufactured with a substrate (14) made of pure zirconium or of zirconium alloy and a multilayer protective coating (16) covering a surface (14B) of the substrate (14), the protective coating (16) comprising a main layer (18) made of pure chromium and one or a plurality of additional layers (20), each additional layer (20) being made of pure chromium or of a material consisting of chromium and, furthermore, of oxygen and/or of nitrogen, with the possible presence of unavoidable impurities.

2. The cladding according to claim 1, wherein at least one additional layer (20) is made of pure chromium, chromium oxide, chromium nitride or chromium oxynitride or of a combination of such materials.

3. The cladding according to claim 1 or claim 2, wherein at least one additional layer (20) is made of metallic chromium doped with oxygen atoms and/or nitrogen atoms or wherein oxygen atoms and/or nitrogen atoms are implanted.

4. The cladding according to any of the preceding claims, comprising a transition layer (22) interposed between the main layer (18) and an additional layer (20) containing oxygen and/or nitrogen, the transition layer (22) being made of metallic chromium doped with oxygen atoms and/or nitrogen atoms or metallic chromium wherein oxygen atoms and/or nitrogen atoms are implanted.

5. The cladding according to claim 4, wherein the transition layer (22) has a concentration of oxygen atoms progressively increasing from the main layer (18) toward the additional layer (20) and/or has a concentration of nitrogen atoms progressively increasing from the main layer (18) toward the additional layer (20).

6. The cladding according to claim 4 or claim 5, wherein the concentration of oxygen atoms of the transition layer (22) at the interface thereof with the adjacent additional layer (20) is substantially equal to the concentration of oxygen atoms of the adjacent additional layer (20) and/or the concentration of nitrogen atoms of the transition layer (22) at the interface with the adjacent additional layer (20) is substantially equal to the concentration of nitrogen atoms of the adjacent additional layer (20).

7. The cladding according to any of the preceding claims, wherein the thickness of the main layer (18) is comprised between 3 μm and 30 μm.

8. The cladding according to any of the preceding claims, wherein the thickness of each additional layer (20) is comprised between 10 nm and 5 μm.

9. The cladding according to any of the preceding claims, wherein an additional layer (20) is located over the main layer (18).

10. A cladding according to any of the preceding claims, wherein an additional layer (20) is located under the main layer (18).

11. A method of manufacturing a nuclear fuel cladding, the manufacturing method comprising:
the provision of a substrate (14) made of pure zirconium or of zirconium alloy; and
the deposition of a multilayer protective coating (16) over a surface (14B) of the substrate (14), the deposition of the protective coating (16) comprising the deposition of a main layer (18) made of pure chromium by physical vapor deposition and the deposition of one or a plurality of additional layers (20), each additional layer (20) being made of pure chromium or of a material consisting of chromium and, furthermore, of oxygen and/or of nitrogen, with the possible presence of unavoidable impurities.

12. The manufacturing method according to claim 11, wherein an additional layer (20) is made of pure chromium, chromium oxide, chromium nitride or chromium oxynitride or of a combination of such materials.

13. The manufacturing method according to claim 11 or claim 12, wherein an additional layer is made of metallic chromium doped with oxygen atoms and/or nitrogen atoms or of metallic chromium wherein oxygen atoms and/or nitrogen atoms are implanted.

14. The manufacturing method according to any of claims 11 to 13, wherein an additional layer (20) is deposited by a physical vapor deposition.

15. The manufacturing method according to any of claims 11 to 14, wherein an additional layer (20) is deposited by physical vapor deposition performed in an atmosphere consisting of a binary or ternary gas mixture containing a neutral gas and, furthermore, of oxygen and/or of nitrogen.

16. The manufacturing method according to any of claims 11 to 15, comprising forming a transition layer (22) interposed between the main layer (18) and an additional layer (20), the transition layer (22) being made of chromium doped with oxygen atoms.

17. The manufacturing method according to claim 16, wherein the transition layer (22) has a concentration of oxygen atoms progressively increasing from the main layer (18) toward the adjacent additional layer (20).

18. The manufacturing method according to any of claims 11 to 17, wherein the thickness of the main layer (18) is comprised between 3 and 30 μm.

19. The manufacturing method according to any of claims 11 to 18, wherein the thickness of each additional layer (20) is comprised between 10 nm and 5.

20. The manufacturing method according to any of claims 11 to 19, wherein at least one additional layer (20) is deposited after the main layer (18).

21. The training method according to any of claims 11 to 20, wherein at least one additional layer (20) is deposited before the main layer (18).

22. A nuclear fuel cladding which can be obtained by a method according to any of claims 11 to 21.
